(19) United States
(12) Patent Application Publication
(10) Pub. No.: US 2021/0335679 A1
(43) Pub. Date: Oct. 28, 2021

(54) DISPLAY PANEL AND REPAIR METHOD THEREOF, AND DISPLAY DEVICE

(71) Applicant: TCL China Star Optoelectronics Technology Co., Ltd., Shenzhen (CN)

(72) Inventor: Dong LUO, Shenzhen (CN)

(73) Assignee: TCL China Star Optoelectronics Technology Co., Ltd., Shenzhen (CN)

(21) Appl. No.: 16/626,552

(22) PCT Filed: Dec. 20, 2019
(86) PCT No.: PCT/CN2019/126938

§ 371 Date: Dec. 25, 2019

(30) Foreign Application Priority Data
Dec. 12, 2019 (CN) 201911272147.5

(51) Int. Cl. H01L 21/66; G02F 1/1362; H01L 27/12

(52) U.S. Cl. CPC H01L 22/22; H01L 27/124; G02F 1/136263; G02F 1/136286

(57) ABSTRACT

A display panel and a repair method for the display panel, and a display device are disclosed. The display panel includes a plurality of horizontally disposed first lines and a plurality of vertically disposed second lines. The first lines intersect with the second lines. Each of the first lines is divided into at least two first sub-lines located at an intersection of each of the first lines and each of the second lines. The two first sub-lines are insulated from each other and arranged in parallel. In this manner, the present invention can increase a success rate of repairing the display panel, and improve yield of the display panel.

### BACKGROUND OF INVENTION

### 1. Field of Invention

The present invention relates to a technical field of displays, and particularly to, a display panel and a repair method thereof, and a display device.

### 2. Related Art

Various defects, such as open circuits or short circuits of gate lines and data lines at sides of thin-film transistors (TFTs), can occur in thin-film transistor (TFT) liquid crystal display (LCD) products during manufacturing processes due to electro-static discharge or too many particles in product environments. As a result, in order to improve yield, it is necessary to take action to fix the different kinds of defects.

When defects of short circuits of gate lines and data lines (GD short for short) of pixels occur at interactions of the gate lines and data lines in active areas (AA), a current method of repairing the damage is to break opposite sides of where the defects occur using laser beams, and to re-connect them with U-shaped long lines. Because of uneven contours of where the repair is performed, the current method has a low success rate of repairing by the long lines, and fails to significantly improve the yield.

### SUMMARY OF INVENTION

A main objective of the present invention is to increase a success rate of repairing a display panel and to improve yield of the display panel.

In order to achieve the above-mentioned objective, the present invention provides a technical solution as follows: the present invention provides a display panel, comprising a plurality of horizontally disposed first lines and a plurality of vertically disposed second lines; wherein the plurality of the first lines intersect with the plurality of the second lines; each of the first lines is divided into at least two first sub-lines located at an intersection of each of the first lines and each of the second lines; and the at least two first sub-lines are insulated from each other and arranged in parallel; and wherein one of the first lines and the gate lines is data lines, and the other one is gate lines.

Further, the at least two first sub-lines are configured to operate independently.

Further, each of the second lines is divided into at least two second sub-lines located at an intersection of each of the second lines and each of the first lines, and the at least two second sub-lines are insulated from each other and arranged in parallel.

Further, the at least two second sub-lines are configured to operate independently.

Further, each of the first lines comprises at least a gap formed between the at least two first sub-lines, and each of the second lines comprises at least a gap formed between the at least two second sub-lines.

Further, the display panel is a thin-film transistor display panel.

In order to overcome the above-mentioned problem, the present invention provides another technical solution as follows: the present invention provides a display device, comprising the display panel as mentioned above.

In order to overcome the above-mentioned problem, the present invention provides another technical solution as follows: the present invention provides a repair method for the aforementioned display panel, the repair method comprising detecting whether the at least two first sub-lines work normally when the first lines fails; and if there is a failure in one of the first sub-lines, the one of the first sub-lines having the failure is to be cut off.

Further, the repair method further comprises detecting whether the at least two second sub-lines work normally when the second lines fails; and if there is a failure in at least one of the second sub-lines, the one of the second sub-lines having the failure is to be cut off.

Further, the one of the first sub-lines having the failure is cut off by a laser beam, and the failure comprises a short circuit or an open circuit.

The present invention has advantageous effects as follows: different from the prior art, the present invention provides a display panel including a plurality of first lines and second lines intersecting with the first lines. Each of the first lines is divided into at least two first sub-lines located at an intersection with the second line, and the at least two first sub-lines are insulated from each other and arranged in parallel. In this manner, when there is a failure in one of the first sub-lines, the one of the first sub-lines having the failure can be cut off, so that the other one of the first sub-lines can still keep on working to maintain operation of the first line, thereby no additional lines are needed to be welded, a surface for repair remains smooth, achieving a low difficulty in repairing, increasing a success rate of repairing, and improving the product yield.

### BRIEF DESCRIPTION OF DRAWINGS

The present invention will be further described below with reference to the accompanying drawings and embodiments.

FIG. 1 is a schematic structural view of a display panel of a first embodiment of the present invention.

FIG. 2 is a schematic structural view of a display panel of a second embodiment of the present invention.

FIG. 3 is a schematic structural view of a first line in accordance with an embodiment of a display panel of the present invention.

FIG. 4 is a schematic structural view of a second line in accordance with an embodiment of a display panel of the present invention.

FIG. 5 is a schematic structural view of a display device of an embodiment of the present invention.

FIG. 6 is a flowchart showing a repair method for the display panel of the first embodiment of the present invention.

FIG. 7 is a flowchart showing a repair method for the display panel of the second embodiment of the present invention.

FIG. 8 is a flowchart showing a repair method for the display panel of a third embodiment of the present invention.

### DESCRIPTION OF PREFERRED EMBODIMENTS

The technical solutions in the embodiments of the present invention will be clearly and completely described in the following with reference to the accompanying drawings in the embodiments. Apparently, the embodiments as described are only a part, but not all, of the embodiments of the present invention. Based on the embodiments in the present invention, all other embodiments obtained by those skilled in the art without creative efforts shall be within the scope of the present invention.

Please refer to FIG. 1. FIG. 1 is a schematic structural view of a display panel of a first embodiment of the present invention. A display panel 10 includes a plurality of horizontally disposed first lines 11 and a plurality of vertically disposed second lines 12, and the plurality of the first lines 11 intersect with the plurality of the second lines 12. Each of the first lines 11 is divided into at least two first sub-lines 111 located at an intersection of each of the first lines 11 and each of the second lines 12. In this embodiment, each of the first lines 11 is divided into two first sub-lines 111. In another embodiment, each of the first lines 11 may be divided into three, four, or even more first sub-lines 111.

In this embodiment, the two first sub-lines 111 are insulated from each other and are arranged in parallel. The two first sub-lines 111 can operate independently due to the parallel arrangement.

In this embodiment, one of the first line 11 and the second line 12 is embodied as a gate line, and the other one is a data line.

In this embodiment, if there is a failure occurred in an intersection of the first line 11 and the second line 12, for example such as a short circuit, detect which one or some of the first sub-lines 111 of the first line 11 are short-circuited, and cut off the one or some of the first sub-lines 111 having the short circuit. The remaining one or some of the first sub-lines 111 continue to carry out a task of transmitting data. No additional lines are needed to be welded, the repair method is simple, and a product yield can be effectively improved.

As described above, in this embodiment, a display panel includes a plurality of first lines and second lines intersecting with each other. Each one of the first lines is divided into at least two first sub-lines located at an intersection of each of the first lines and each of the second lines, and the at least two first sub-lines are insulated from each other and arranged in parallel. In this manner, when there is a failure in one of the first sub-lines, the one of the first sub-lines having the failure is to be cut off, while another one of the first sub-lines can still keep on working, so that operation of the first line can be maintained. In this manner, no additional lines are needed to be welded, so that a surface for repair remains smooth, and difficulty in repairing is low, thereby increasing a success rate of repairing and improving the product yield.

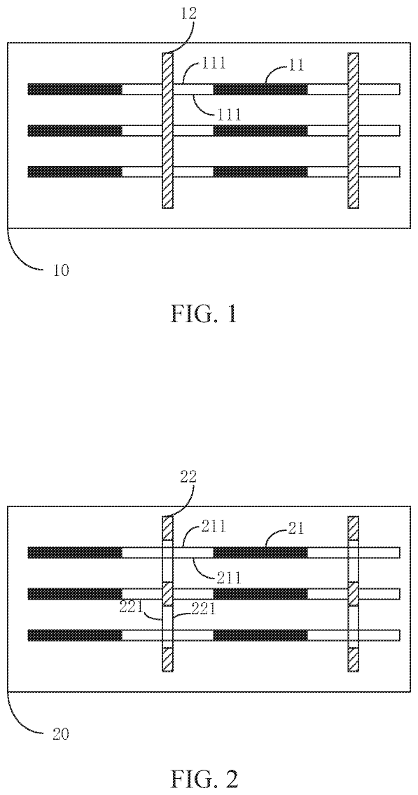

Please refer to FIG. 2 showing a schematic structural view of a display panel of a second embodiment of the present invention. A display panel 20 includes a plurality of horizontally disposed first lines 21 and a plurality of vertically disposed second lines 22, and the plurality of the first lines 21 intersect with the plurality of the second lines 22. Each of the second lines 22 is divided into at least two second sub-lines 221 located at an intersection of each of the second lines 22 and each of the first lines 21, and each of the first lines 21 is divided into at least two first sub-lines 211 located at an intersection of each of the first lines 21 and each of the second lines 22. In this embodiment, each of the first lines 11 is divided into two first sub-lines 211. In another embodiment, each of the first lines 11 may be divided into three, four, or even more first sub-lines 211. In this embodiment, each of the second lines 21 is divided into two second sub-lines 221. In another embodiment, each of the second lines 22 may be divided into three, four, or even more second sub-lines 221.

In this embodiment, the two first sub-lines 211 are insulated from each other and are arranged in parallel. The two first sub-lines 211 can operate independently due to the parallel arrangement. The two second sub-lines 221 are insulated from each other and are arranged in parallel. The two first sub-lines 221 can operate independently due to the parallel arrangement.

In this embodiment, one of the first line 11 and the second line 12 is embodied as a gate line, and the other one is a data line.

In this embodiment, if there is a failure occurred in an intersection of the first line 21 and the second line 22, for example such as a short circuit, detect which one or some of the first sub-lines 211 of the first line 21 are short-circuited, and cut off the one or some of the first sub-lines 211 having the short circuit. The remaining one or some of the first sub-line 211 continue to carry out a task of transmitting data. If there is a failure occurred in an intersection of the first line 21 and the second line 22, for example such as a short circuit, detect which one or some of the second sub-lines 221 of the second line 22 are short-circuited, and cut off the one or some of the second sub-lines 221 having the short circuit. The remaining one or some of the second sub-lines 211 continue to carry out a task of transmitting data. In this manner, when the failure occurs in the first sub-lines or the second sub-lines, no additional lines are needed to be welded, so that the repair method is simple, and a product yield can be effectively improved.

In this embodiment, the display panel 20 is a thin-film transistor display panel. In another embodiment, the display panel 20 may be an organic-light emitting diode (OLED) display panel.

It should be noted that in this embodiment, number of the first sub-lines 211 included in the first lines 21 is the same as that of the second sub-lines 221 included in the second lines 22. In another embodiment, number of the first sub-lines 211 included in the first lines 21 is not the same as that of the second sub-lines 221 included in the second lines 22, and can be varied according to practical applications. In a same display panel, number of the first sub-lines 211 included in different one of the first lines 21 may be the same or different. Number of the first sub-lines 211 of a same first line 21 at intersections with different second lines 22 may be the same or different. Likewise, in a same display panel, number of the second sub-lines 221 included in different one of the second lines 22 may be the same or different. Number of the second sub-lines 221 of a same second line 22 at intersections with different first lines 21 may be the same or different.

As described above, in this embodiment, each of the first lines is divided into at least two first sub-lines located at an intersection of each of the first lines and each of the second lines, and each of the second lines is divided into at least two second sub-lines located at an intersection of each of the first lines and each of the second lines. In this manner, when there is a failure in one of the first sub-lines, the one of the first sub-lines having the failure is to be cut off, while another one of the first sub-lines can still keep on working, so that operation of the first line can be maintained. When there is a failure in one of the second sub-lines, the one of the second sub-lines having the failure is to be cut off, while another one of the second sub-lines can still keep on working. In this manner, no additional lines are needed to be welded, so that a surface for repair remains smooth, and difficulty in repairing is low, thereby increasing a success rate of repairing and improving the product yield.

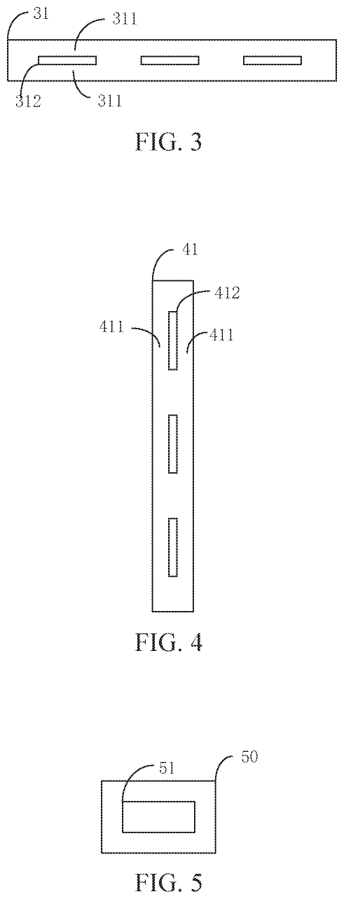

Please refer to FIGS. 3 and 4. FIG. 3 is a schematic structural view of a first line in accordance with an embodiment of a display panel of the present invention. FIG. 4 is a schematic structural view of a second line in accordance with an embodiment of a display panel of the present invention. The first line 31 includes two first sub-lines 311, wherein the first sub-lines 311 may be configured by a gap 312 formed in the first line 31 in such a way that the gap is formed between the first sub-lines. In another embodiment, the first line 31 includes N number of the first sub-lines 311, wherein N is an integer greater than or equal to two, and the N number of the first sub-lines 311 may be achieved by N−1 number of the gaps 312 formed in the first line 31.

Likewise, the second line 32 includes two second sub-lines 321, wherein the second sub-lines 321 may be configured by a gap 322 formed in the second line 32 in such a way that the gap is formed between the second sub-lines. In another embodiment, the second line 32 includes N number of the second sub-lines 321, wherein N is an integer greater than or equal to two, and the N number of the second sub-lines 321 may be achieved by N−1 number of the gaps 322 formed in the second line 32.

As described above, in this embodiment, each of the first line and the second line is configured with at least a gap inside to form at least two first sub-lines and two sub-lines, so that their formation can be easily and simply achieved without taking up additional space.

Please refer to FIG. 5. FIG. 5 is a schematic structural view of a display device of an embodiment of the present invention. A display device 50 includes a display panel 51. The display panel 51 is the display panel shown in FIGS. 1 and 2.

As described above, in this embodiment, no additional lines are needed to be welded when repairing the display panel of the display device, so that a surface for repair remains smooth, and difficulty in repairing is low, thereby increasing a success rate of repairing and improving the product yield.

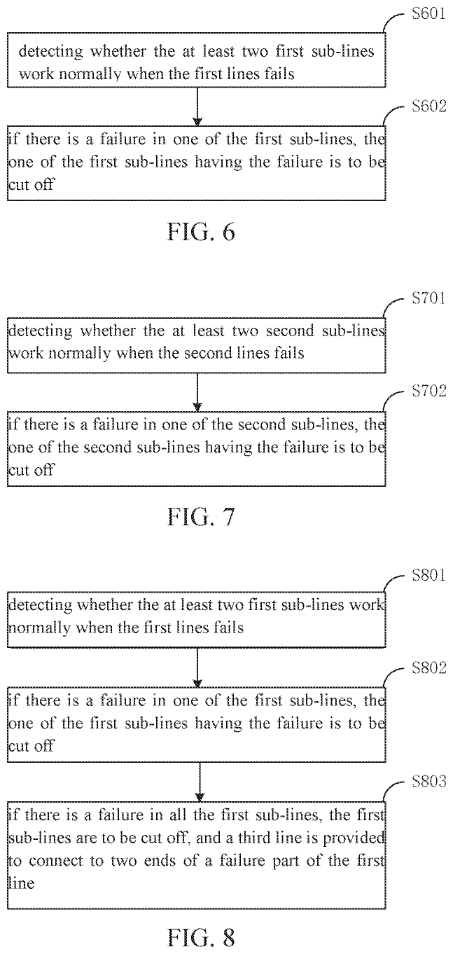

Please refer to FIG. 6. FIG. 6 is a flowchart showing a repair method for the display panel of the first embodiment of the present invention. The repair method for the display panel of the present invention includes:

S601: detecting whether the at least two first sub-lines work normally when the first lines fails.

In a specific embodiment, a failure in the first line of the display panel is detected, wherein the display panel is the display panel shown in FIG. 1 or FIG. 2. First, determine whether the failure occurs in an intersection of the first line and the second line. If so, further judge whether the at least two first sub-lines at the intersection work normally. Specifically, each of the first sub-lines can be separately detected to judge whether it works normally.

S602: if there is a failure in one of the first sub-lines, the one of the first sub-lines having the failure is to be cut off.

In a specific embodiment, if there is a failure occurred in at least one of the first sub-lines, such as a short circuit or an open circuit, cut off the one of the first sub-lines having the failure using a laser beam. The other one of the first sub-lines working normally remains. Because the other first sub-line can operate independently, in this embodiment, no additional lines are needed to be re-connected, so that the repair method is simple, a surface remains smooth, work performance is great, and product yield is high.

As described above, in this embodiment, detect whether the at least two first sub-lines work normally when the first lines fails, and if there is a failure in one of the first sub-lines, cut off the one of the first sub-lines having the failure. Because the remaining one of the first sub-lines can still carry out a task of transmitting data, no additional lines are needed to be re-connected, so that a surface for repair remains smooth, repair efficiency is high, thereby effectively improving a product yield.

Please refer to FIG. 7. FIG. 7 is a flowchart showing a repair method for the display panel of the second embodiment of the present invention. The repair method for the display panel of the present invention includes:

S701: detecting whether the at least two second sub-lines work normally when the second lines fails.

In a specific embodiment, a failure in the second line of the display panel is detected, wherein the display panel is the display panel shown in FIG. 2. First, determine whether the failure occurs in an intersection of the second line and the first line. If so, further judge whether the at least two second sub-lines at the intersection work normally. Specifically, each of the second sub-lines can be separately detected to judge whether it works normally.

S702: if there is a failure in one of the second sub-lines, the one of the second sub-lines having the failure is to be cut off.

In a specific embodiment, if there is a failure occurred in at least one of the second sub-lines, such as a short circuit or an open circuit, cut off the one of second sub-lines having the failure using a laser beam. The other one of the second sub-lines working normally remains. Because the other second sub-line can operate independently, in this embodiment, no additional lines are needed to be re-connected, so that the repair method is simple, a surface remains smooth, work performance is great, and product yield is high.

As described above, in this embodiment, detect whether the at least two second sub-lines work normally when the second lines fails, and if there is a failure in one of the second sub-lines, cut off the one of the second sub-lines having the failure. Because the remaining one of the second sub-lines can still carry out a task of transmitting data, no additional lines are needed to be re-connected, so that a surface for repair remains smooth, repair efficiency is high, thereby effectively improving a product yield.

Please refer to FIG. 8. FIG. 8 is a flowchart showing a repair method for the display panel of a third embodiment of the present invention. The repair method for the display panel of the present invention includes:

S801: detecting whether the at least two first sub-lines work normally when the first lines fails.

S802: if there is a failure in one of the first sub-lines, the one of the first sub-lines having the failure is to be cut off.

In a specific embodiment, steps S801-S802 are basically the same as steps S601-S602 in the first embodiment of the repair method for the display panel of the present invention, and will not be repeated here.

S803: if there is a failure in all the first sub-lines, the first sub-lines are to be cut off, and a third line is provided to connect to two ends of a failure part of the first line.

In a specific embodiment, if a failure is found in all the first sub-lines, cut off all the first sub-lines and dispose a third line. The third line connects to two ends of a failure part of the first line, so that the two ends of the failure part of the first line are connected through the third line, and signals to be transmitted by the first line is transmitted through the third line.

As described above, in this embodiment, if all the first sub-lines of the first line are found to have a failure, a third line is provided to connect two ends of a failure part of the first line for keeping a normal operation of the first line, thereby to ensure that display panel can work normally after repair and to avoid a waste of resources.

Different from the prior art, in the present invention, each of the first lines is divided into at least two first sub-lines located at an intersection with the second line, and the at least two first sub-lines are insulated from each other and arranged in parallel. In this manner, when there is a failure in one of the first sub-lines, the one of the first sub-lines having the failure can be cut off, so that the other one of the first sub-lines can still keep on working to maintain operation of the first line, thereby no additional lines are needed to be welded, a surface for repair remains smooth, achieving a low difficulty in repairing, increasing a success rate of repairing, and improving the product yield.

The above description is only an embodiment of the present invention, and thus does not limit the patent scope of the present invention. Any equivalent structure or equivalent process transformation made by using the description and drawings of the present invention, or directly or indirectly used in other related technical fields, is also included in the scope of patent protection of the present invention.

What is claimed is:

1. A display panel, comprising:
a plurality of horizontally disposed first lines and a plurality of vertically disposed second lines;
wherein the plurality of the first lines intersect with the plurality of the second lines; each of the first lines is divided into at least two first sub-lines located at an intersection of each of the first lines and each of the second lines; and the at least two first sub-lines are insulated from each other and arranged in parallel; and
wherein one of the first lines and the gate lines is data lines, and the other one is gate lines.

2. The display panel of claim 1, wherein the at least two first sub-lines are configured to operate independently.

3. The display panel of claim 2, wherein each of the second lines is divided into at least two second sub-lines located at an intersection of each of the second lines and each of the first lines, and the at least two second sub-lines are insulated from each other and arranged in parallel.

4. The display panel of claim 3, wherein the at least two second sub-lines are configured to operate independently.

5. The display panel of claim 4, wherein each of the first lines comprises at least a gap formed between the at least two first sub-lines, and each of the second lines comprises at least a gap formed between the at least two second sub-lines.

6. The display panel of claim 4, wherein the display panel is a thin-film transistor display panel.

7. A display device, comprising a display panel, the display panel comprising:
a plurality of horizontally disposed first lines and a plurality of vertically disposed second lines;
wherein the plurality of the first lines intersect with the plurality of the second lines; each of the first lines is divided into at least two first sub-lines located at an intersection of each of the first lines and each of the second lines; and the at least two first sub-lines are insulated from each other and arranged in parallel; and
wherein one of the first lines and the gate lines is data lines, and the other one is gate lines.

8. The display device of claim 7, wherein the at least two first sub-lines are configured to operate independently.

9. The display device of claim 8, wherein each of the second lines is divided into at least two second sub-lines located at an intersection of each of the second lines and each of the first lines, and the at least two second sub-lines are insulated from each other and arranged in parallel.

10. The display device of claim 9, wherein the at least two second sub-lines are configured to operate independently.

11. The display device of claim 10, wherein each of the first lines comprises at least a gap formed between the at least two first sub-lines, and each of the second lines comprises at least a gap formed between the at least two second sub-lines.

12. The display device of claim 10, wherein the display panel is a thin-film transistor display panel.

13. A repair method for the display panel of claim 1, the repair method comprising:
detecting whether the at least two first sub-lines work normally when the first lines fails; and
if there is a failure in one of the first sub-lines, the one of the first sub-lines having the failure is to be cut off.

14. The repair method of claim 13, further comprising:
detecting whether the at least two second sub-lines work normally when the second lines fails; and
if there is a failure in at least one of the second sub-lines, the one of the second sub-lines having the failure is to be cut off.

15. The repair method of claim 13, wherein the one of the first sub-lines having the failure is cut off by a laser beam, and the failure comprises a short circuit or an open circuit.
